(19) United States
(12) Patent Application Publication
(10) Pub. No.: US 2026/0186172 A1
(43) Pub. Date: Jul. 2, 2026

(54) LENS

(71) Applicant: SAMSUNG ELECTRO-MECHANICS CO., LTD., Suwon-si (KR)

(72) Inventors: Tae Kyung LEE, Suwon-si (KR); Jae Hyoung GIL, Suwon-si (KR); Na Yi KANG, Suwon-si (KR); Byung Ju KIM, Suwon-si (KR); Joung Hun KIM, Suwon-si (KR); Eul Doo PARK, Suwon-si (KR); Shin Young PARK, Suwon-si (KR)

(73) Assignee: SAMSUNG ELECTRO-MECHANICS CO., LTD., Suwon-si (KR)

(21) Appl. No.: 19/365,574

(22) Filed: Oct. 22, 2025

(30) Foreign Application Priority Data
Dec. 27, 2024 (KR) 10-2024-0198965

(51) Int. Cl. G02B 1/14; G02B 1/11

(52) U.S. Cl. CPC G02B 1/14; G02B 1/11

(57) ABSTRACT

A lens includes a lens portion, an anti-reflection (AR) coating layer disposed on a surface of the lens portion, and a water-repellent layer disposed on a surface of the AR coating layer. The water-repellent layer includes an inorganic layer having a plurality of pores and an organic layer at least partially disposed in the plurality of pores. The inorganic layer includes silicon oxynitride (SiOₓN_{y}).

### CROSS-REFERENCE TO RELATED APPLICATIONS

This application claims the benefit under 35 USC 119(a) of Korean Patent Application No. 10-2024-0198965 filed on Dec. 27, 2024, in the Korean Intellectual Property Office, the entire disclosure of which is incorporated herein by reference for all purposes.

### BACKGROUND

### 1. Field

The present disclosure relates to a lens.

### 2. Description of the Background

Recently, technologies related to automotive electronics, such as advanced driver assistance systems (ADAS) and autonomous driving, have been continuously developed, and accordingly, demand for automotive camera modules and optical sensors has been increasing.

In particular, the market for camera modules using lenses has been rapidly increasing, and camera modules installed in vehicles have been adopted in various positions, such as a front portion, a rear portion, and side portions.

Vehicle cameras are constantly in a state of being exposed to external environments, such that defects such as foreign matter adhesion, lens surface contamination, and scratches may frequently occur due to environmental factors. Such defects may significantly affect the performance of a camera module.

To consistently obtain clear images, an outermost lens of a lens used for automotive electronics may require self-cleaning technology. To this end, a hydrophobic coating may be generally applied thereto, such that water droplets and contaminants that come into contact with a lens may easily roll off due to a high contact angle.

However, a hydrophobic coating may be formed by deposition of an organic material, and thus may be susceptible to physical damage caused by external forces, which may result in damage to the hydrophobic coating. As a result, a self-cleaning effect may be reduced, and it may be difficult to obtain clear images. Accordingly, a hydrophobic coating having high durability may be necessary.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a lens includes a lens portion, an anti-reflection (AR) coating layer disposed on a surface of the lens portion, and a water-repellent layer disposed on a surface of the AR coating layer. The water-repellent layer includes an inorganic layer having a plurality of pores and an organic layer at least partially disposed in the plurality of pores. The inorganic layer includes silicon oxynitride (SiOₓN_{y}).

The plurality of pores may be formed in the inorganic layer, and the organic layer may penetrate into the inorganic layer.

The organic layer may include fluorine-carbon.

The organic layer may include a Si head group, and the Si head group may form a bond with silicon (Si) of the inorganic layer.

The inorganic layer may include a nitrogen (N) content higher than an oxygen (O) content.

The AR coating layer may include at least one low-refractive-index layer and at least one high-refractive-index layer.

The low-refractive-index layer may include a first layer formed of SiO₂, and the high-refractive-index layer may include a second layer formed of TiO₂.

The high-refractive-index layer may include a third layer formed of a nitride-based material.

The third layer may include at least one of AlN, Si₃N₄, AlON, and SiON.

The low-refractive-index layer may include a fourth layer formed of a nitride-based material.

The fourth layer may include at least one of TiN AND TiON.

In another general aspect, a lens includes a lens portion, an anti-reflection (AR) coating layer disposed on a surface of the lens portion, and a water-repellent layer disposed on a surface of the AR coating layer, wherein the water-repellent layer includes an inorganic layer having a plurality of pores and an organic layer at least partially disposed in the plurality of pores, and the inorganic layer includes silicon nitride (SiₓN_{y}).

Other features and aspects will be apparent from the following detailed description, the drawings, and the claims.

### BRIEF DESCRIPTION OF DRAWINGS

FIG. 1 is a schematic perspective view of a lens according to an example embodiment of the present disclosure.

FIG. 2 is a cross-sectional view of portion “A” in FIG. 1.

FIG. 3 is a diagram illustrating a structure of a water-repellent layer illustrated in FIG. 2.

FIGS. 4 to 14 are cross-sectional views of various example embodiments related to arrangement of an AR coating layer of the present disclosure.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

An aspect of the present disclosure is to provide a lens having improved wear resistance and weather resistance.

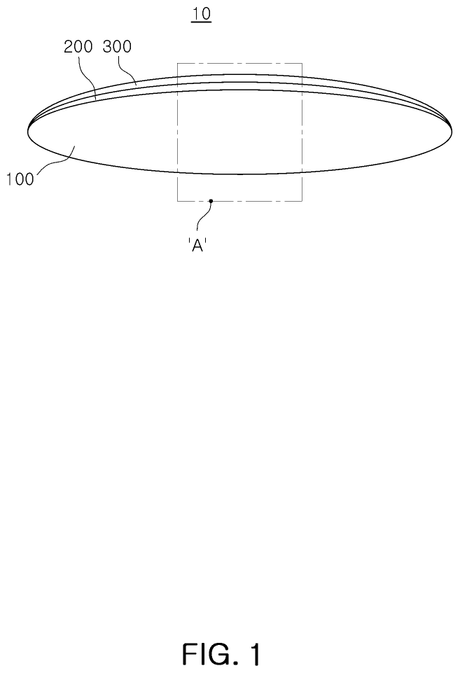

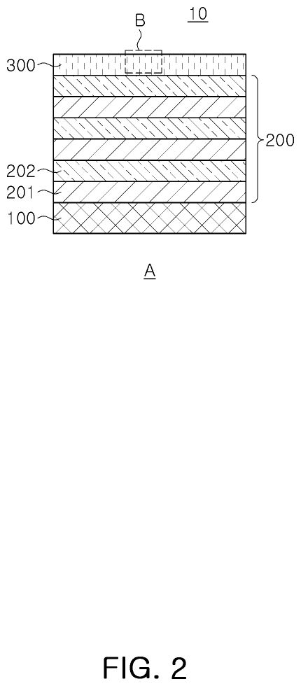

FIG. 1 is a schematic perspective view of a lens according to an example embodiment of the present disclosure. FIG. 2 is a cross-sectional view of portion “A” in FIG. 1.

Referring to FIGS. 1 and 2, a lens 10 according to an example embodiment of the present disclosure may include a lens portion 100, an anti-reflection (AR) coating layer 200, and a water-repellent layer 300.

A shape or type of the lens portion 100 is not limited, and the lens portion 100 may be implemented in a form applicable to an optical device such as a camera module or the like.

Accordingly, the shape of the lens portion 100 may be modified into forms other than that illustrated in FIG. 1.

The lens portion 100 may be formed of glass. However, the lens portion 100 may also be formed of other materials, for example, a plastic resin including a resin element.

For example, the plastic resin may include at least one of polycarbonate and polyolefin.

Here, polyolefin may include at least one of a cycloolefin polymer and a cycloolefin copolymer.

The AR coating layer 200 may be disposed on one surface of the lens portion 100. The AR coating layer 200 may serve to reduce reflectance on a surface of the lens 10, thereby reducing or preventing a flare phenomenon.

Referring to FIG. 2, the AR coating layer 200 may include at least one low-refractive-index layer and at least one high-refractive-index layer. That is, the AR coating layer 200 may include a first layer 201 and a second layer 202 having different refractive indices, and the first layer 201 and the second layer 202 may be alternately stacked one or more times to form a multilayer structure.

The high and low refractive indices may be distinguished from each other based on a refractive index of 1.5. Accordingly, a low-refractive-index material may be a material having a refractive index less than 1.5, and a high-refractive-index material may be a material having a refractive index of 1.5 or more.

The first layer 201 may be a low-refractive-index layer, and may be formed of SiO₂. The second layer 202 may be a high-refractive-index layer, and may be formed of TiO₂.

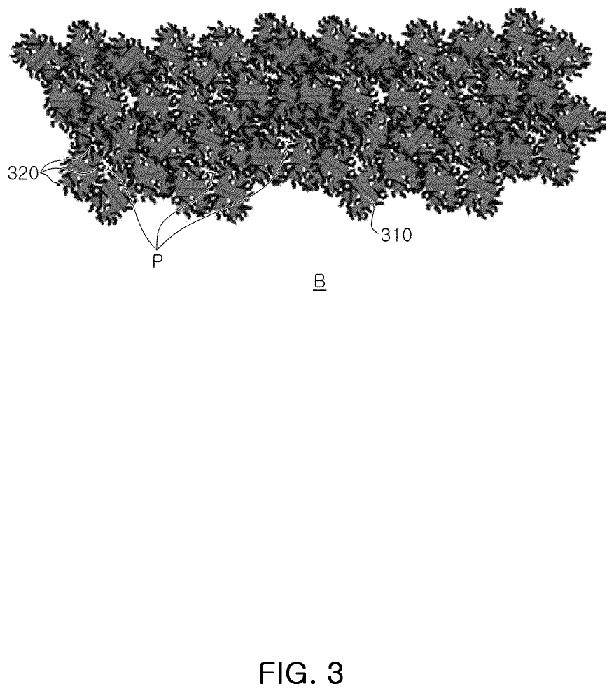

The water-repellent layer 300 may be disposed on one surface of the AR coating layer 200. The water-repellent layer 300 may perform a function of preventing surface oxidation of the lens portion 100 or the like. The water-repellent layer may include an inorganic layer and an organic layer. A structure of the water-repellent layer will be described below with reference to FIG. 3.

The water-repellent layer 300 may include an inorganic layer 310 having a plurality of pores P and an organic layer 320 at least partially disposed in the plurality of pores.

SiO₂ having an inorganic porous structure may be easily dissolved by an ionized alkali metal or the like under harsh environmental conditions. When SiO₂ is dissolved, the organic water-repellent layer formed thereon may also be lost together, causing the water-repellent layer to lose the function thereof.

In the water-repellent layer 300 of the lens 10 according to the present disclosure, the inorganic layer 310 may be formed of a robust material, and the organic layer 320 may penetrate into the inorganic layer 310 through the pores P formed in the inorganic layer 310 to form an inorganic-organic composite layer.

The inorganic layer 310 may include silicon oxynitride (SiOₓN_{y}) as an amorphous inorganic material. In the present disclosure, in order to improve a property of SiO₂ being easily dissolved by water or the like, an inorganic layer may be formed by mixing SiO₂ and silicon nitride (Si₃N₄) having high durability. Silicon nitride (Si₃N₄) may have higher resistance to water, metal ions, or the like than SiO₂. Nitrogen (N) may form a strong bond with a silicon (Si) atom to suppress a reaction with water, metal ions, or the like and reduce a dissolution phenomenon. Accordingly, when the inorganic layer 310 is formed by mixing SiO₂ and silicon nitride (Si₃N₄), chemical durability of the water-repellent layer 300 may be improved. However, the present disclosure is not limited thereto. As will be described below, the inorganic layer 310 may be formed solely of silicon nitride (SiₓN_{y}).

Silicon oxynitride (SiOₓN_{y}) may be in a non-stoichiometric state. X and Y may mean that an atomic ratio of oxygen (O) between nitrogen (N) is variable. Values of x and y may vary depending on deposition conditions.

The inorganic layer 310 may have a nitrogen (N) content higher than an oxygen (O) content. When SiO₂ and silicon nitride (Si₃N₄) are mixed, increasing a silicon nitride content may reduce a dissolution phenomenon. Thus, the inorganic layer 310, having a nitrogen content higher than an oxygen content, may be advantageous for improving the dissolution phenomenon.

Referring to FIG. 3, the inorganic layer 310 may be formed of amorphous silicon oxynitride (SiOₓN_{y}), and a plurality of pores P may be formed in the inorganic layer 310. The organic layer 320 may penetrate into the inorganic layer 310 through the pores P.

The organic layer 320 may be at least partially disposed in the plurality of pores P. The organic layer 320 may penetrate into the inorganic layer 310 through the plurality of pores P, and may form a robust composite structure. Accordingly, even when the organic layer is partially damaged, a water-repellent layer 300 having high durability may be formed.

The organic layer 320 may form a bond with the inorganic layer 310. Specifically, the organic layer 320 may form a bond with a bonding site such as a silanol group (Si—OH) present on a surface of the inorganic layer 310.

The organic layer 320 may include fluoro-carbon. Fluorine (F) in the fluoro-carbon may exhibit high water repellency due to high electronegativity and low reactivity, and may impart hydrophobic properties to the organic layer 320. Fluorine-carbon may exhibit a chain structure, and water-repellent performance may be controlled by a length and arrangement of a chain.

The organic layer 320 may include a Si head group. The Si head group may form a chemical bond, such as Si—O—Si, by a condensation reaction with the above-described silanol group (Si—OH) of the inorganic layer 310.

According to a modification, the inorganic layer 310 may include silicon nitride (SiₓN_{y}) as an amorphous inorganic material. That is, the inorganic layer 310 may be formed solely of silicon nitride (SiₓN_{y}), without using SiO₂.

In a structure in which silicon nitride (SiₓN_{y}) is solely included, the inorganic layer 310 may have higher stability and durability. That is, it may be effective in improving a dissolution phenomenon. However, as compared to a case in which silicon nitride (SiₓN_{y}) and SiO₂ are mixed, the organic layer 320 may bond to a relatively small number of sites.

When the inorganic layer 310 is formed of silicon nitride (SiₓN_{y}), the organic layer 320 may form a bond with an amino group (Si—NH) present on a surface of the inorganic layer 310. An unshared electron pair of the amino group (Si—NH) may provide reactivity, and may form a hydrogen bond and a van der Waals force with the Si head group of the organic layer 320.

The water-repellent layer 300 may be formed on one surface of the AR coating layer 200, using an E-beam deposition process or a thermal deposition process. First, the inorganic layer 310 may be deposited using the E-beam deposition process. Subsequently, the organic layer 320 may be deposited on the inorganic layer 310 using the thermal deposition process. During thermal deposition, the organic layer 320 may penetrate into the inorganic layer 310 through the plurality of pores, and the organic layer 320 may form the above-described condensation reaction or hydrogen bond with the inorganic layer 310.

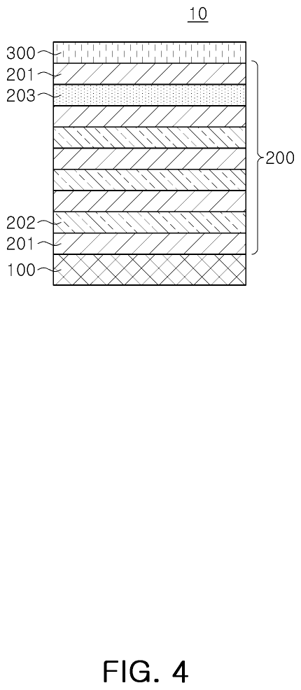

FIGS. 4 to 14 are cross-sectional views of various example embodiments related to arrangement of an AR coating layer of the present disclosure.

Referring to FIGS. 4 to 14, the AR coating layer of the present disclosure may further include a third layer 203 or a fourth layer 204 formed of a nitride-based material.

When the AR coating layer 200 is configured to include only the above-described first layer 201 and second layer 202, an oxide-based material such as TiO₂, SiO₂, or the like may have low hardness, and thus may be susceptible to scratches on a lens surface caused by external environments.

The AR coating layer of the present disclosure may further include the third layer and the fourth layer formed of a nitride-based material, and may have improved durability.

In order to increase the hardness of the AR coating layer, a nitride-based material, rather than an oxide-based material, may be preferably selected. More specifically, TiN and TiON may be used as materials substitutable for SiO₂, which is a low-refractive-index material, and AlN, Si₃N₄, AlON, and SiON may be used as materials substitutable for TiO₂, which is a high-refractive-index material.

Accordingly, the high-refractive-index layer of the AR coating layer may include the third layer 203 formed of a nitride-based material, and the third layer 203 may include at least one of AlN, Si₃N₄, AlON, and SiON. The low-refractive-index layer of the AR coating layer may include the fourth layer 204 formed of a nitride-based material, and the fourth layer 204 may include at least one of TiN and TiON.

When a bandgap is smaller than photon energy at a given wavelength, incident photons may not transmit through a layer and may be absorbed. In addition, when a material has a significantly low bandgap close to a conduction band and valence band, reflection may occur. Accordingly, the nitride-based materials of the third layer and the fourth layer 203 and 204 described above may have a bandgap greater than 3.1 eV.

In the following example embodiments, all or part of the first layer of the AR coating layer 200 may be replaced with the fourth layer 204, which is a low-refractive-index layer, or all or part of the second layer of the AR coating layer 200 may be replaced with the third layer 203, which a high-refractive-index layer.

Referring to FIG. 4, the AR coating layer 200 may be formed by alternately stacking the first layer 201 and the second layer 202 from the bottom, and the third layer 203, which is a high-refractive-index layer, may be disposed below the first layer 201, which is an uppermost low-refractive-index layer.

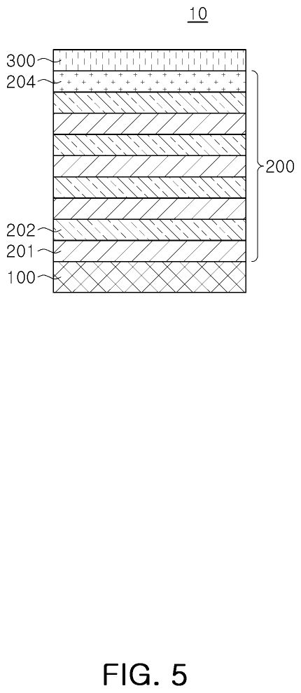

Referring to FIG. 5, the AR coating layer 200 may be formed by alternately stacking the first layer 201 and the second layer 202 from the bottom, and the fourth layer 204, which is a low-refractive-index layer, may be disposed above the second layer 202, which is an uppermost high-refractive-index layer.

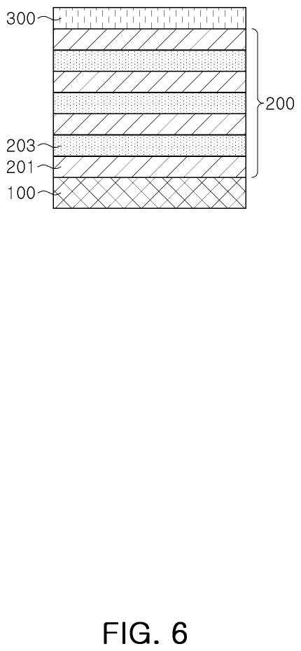

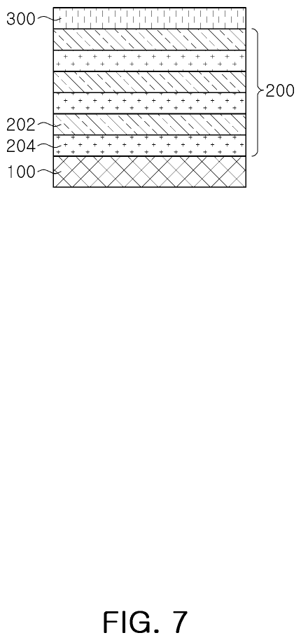

FIGS. 6 and 7 are cross-sectional views of an AR coating layer formed by alternately stacking an oxide-based material and a nitride-based material.

Referring to FIG. 6, the AR coating layer 200 may have a structure in which the first layer 201, which is a low-refractive-index layer and is formed of an oxide-based material, and the third layer 203, which is a high-refractive-index layer and is formed of a nitride-based material, are alternately stacked.

Referring to FIG. 7, the AR coating layer 200 may have a structure in which the second layer 202, which is a high-refractive-index layer and is formed of an oxide-based material, and the fourth layer 204, which is a low-refractive-index layer and is formed of a nitride-based material, are alternately stacked.

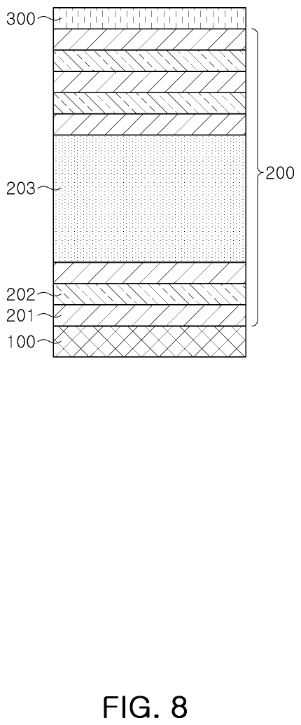

FIGS. 8 to 11 are cross-sectional views of a thick layer, formed of a nitride-based material, disposed on an intermediate portion of an AR coating layer.

Referring to FIG. 8, the AR coating layer 200 may be formed by alternately stacking the first layer 201 and the second layer 202 from the bottom, and the third layer 203, which is a high-refractive-index layer, may be disposed above the first layer 201, which is a low-refractive-index layer of an intermediate portion. In this case, the third layer 203 may be relatively thicker than the first and second layers 201 and 202.

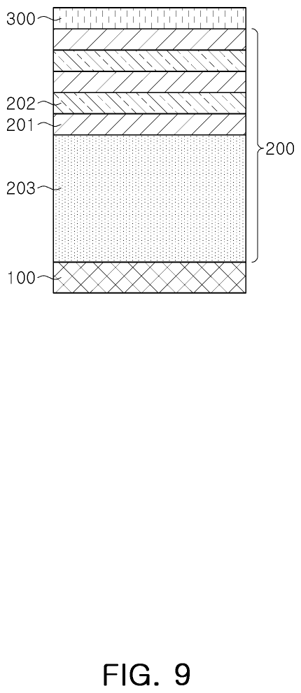

Referring to FIG. 9, the AR coating layer 200 may include the third layer 203, which is a high-refractive-index layer, disposed from the bottom. The first layer 201 and the second layer 202 may be alternately stacked on the third layer 203. In this case, the third layer 203 may be relatively thicker than the first and second layers 201 and 202.

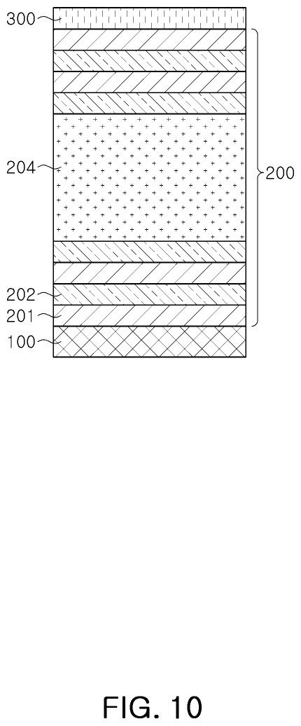

Referring to FIG. 10, the AR coating layer 200 may be formed by alternately stacking the first layer 201 and the second layer 202 from the bottom, and the fourth layer 204, which is a low-refractive-index layer, may be disposed above second layer 202, which is a high-refractive-index layer of an intermediate portion. In this case, the fourth layer 204 may be relatively thicker than the first and second layers 201 and 202.

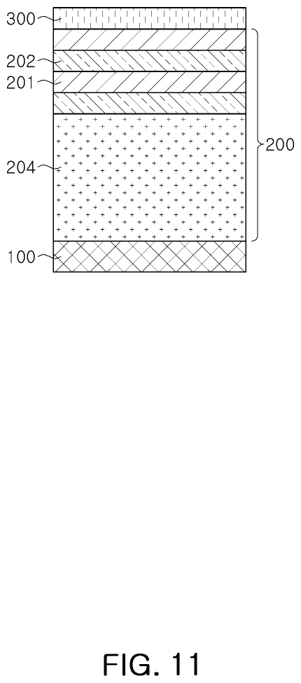

Referring to FIG. 11, the AR coating layer 200 may have the fourth layer 204, which is a low-refractive-index layer, disposed from the bottom. The second layer 202 and the first layer 201 may be alternately stacked on the fourth layer 204. In this case, the fourth layer 204 may be relatively thicker than the first and second layers 201 and 202.

As described, when the thick third layer or fourth layer 203 or 204, formed of a nitride-based material, is disposed on an intermediate portion of the AR coating layer, the third or fourth layer 203 or 204 may serve as a matrix, thereby further improving the overall hardness of the lens.

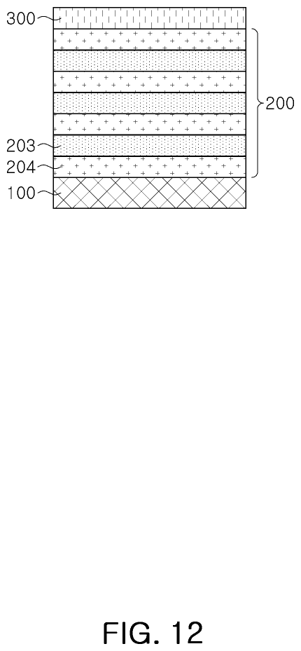

FIGS. 12 to 14 illustrate an AR coating layer formed solely of a nitride-based material.

Referring to FIG. 12, the AR coating layer 200 may have a structure in which the fourth layer 204 and the third layer 203 are alternately stacked from the bottom.

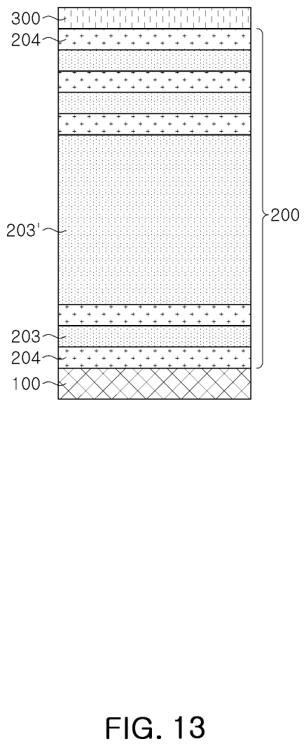

Referring to FIG. 13, the AR coating layer 200 may have a structure in which a third layer 203', thicker than the third and fourth layers 203 and 204, is disposed on an intermediate portion in the structure of FIG. 12.

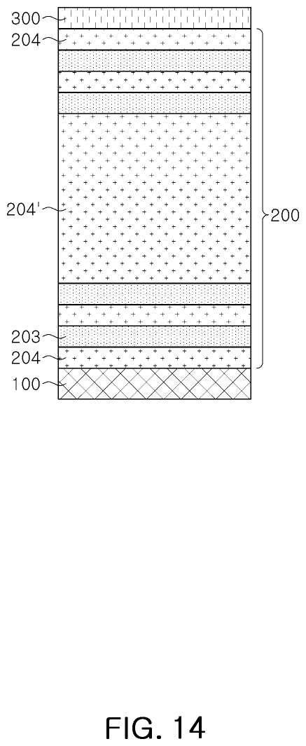

Referring to FIG. 14, the AR coating layer 200 may have a structure in which a fourth layer 204', thicker than the third and fourth layers 203 and 204, is disposed on an intermediate portion in the structure of FIG. 12.

According to example embodiments of the present disclosure, a lens may have improved wear resistance and weather resistance.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A lens comprising:
a lens portion;
an anti-reflection (AR) coating layer disposed on a surface of the lens portion; and
a water-repellent layer disposed on a surface of the AR coating layer,
wherein the water-repellent layer comprises an inorganic layer having a plurality of pores and an organic layer at least partially disposed in the plurality of pores, and
wherein the inorganic layer comprises silicon oxynitride (SiOₓN_{y}).

2. The lens of claim 1, wherein
the plurality of pores are in the inorganic layer, and
the organic layer is penetrated into the inorganic layer.

3. The lens of claim 1, wherein the organic layer comprises fluorine-carbon.

4. The lens of claim 1, wherein
the organic layer comprises a Si head group, and
the Si head group forms a bond with silicon (Si) of the inorganic layer.

5. The lens of claim 1, wherein the inorganic layer comprises a nitrogen (N) content higher than an oxygen (O) content.

6. The lens of claim 1, wherein the AR coating layer comprises at least one low-refractive-index layer and at least one high-refractive-index layer.

7. The lens of claim 6, wherein
the low-refractive-index layer comprises a first layer of SiO₂, and
the high-refractive-index layer comprises a second layer of TiO₂.

8. The lens of claim 6, wherein the high-refractive-index layer comprises a third layer of a nitride-based material.

9. The lens of claim 8, wherein the third layer comprises at least one of AlN, Si₃N₄, AlON, and SiON.

10. The lens of claim 6, wherein the low-refractive-index layer comprises a fourth layer of a nitride-based material.

11. The lens of claim 10, wherein the fourth layer comprises at least one of TiN and TiON.

12. A lens comprising:
a lens portion;
an anti-reflection (AR) coating layer disposed on a surface of the lens portion; and
a water-repellent layer disposed on a surface of the AR coating layer,
wherein the water-repellent layer comprises an inorganic layer having a plurality of pores and an organic layer at least partially disposed in the plurality of pores, and
wherein the inorganic layer comprises silicon nitride (SiₓN_{y}).

13. The lens of claim 12, wherein
the plurality of pores are in the inorganic layer, and
the organic layer is penetrated into the inorganic layer.

14. The lens of claim 12, wherein the organic layer comprises fluorine-carbon.

15. The lens of claim 12, wherein
the organic layer comprises a Si head group, and
the Si head group forms a bond with silicon (Si) of the inorganic layer.

16. The lens of claim 12, wherein the AR coating layer comprises at least one low-refractive-index layer and at least one high-refractive-index layer.
